(19) United States
(12) Patent Application Publication
(10) Pub. No.: US 2008/0283825 A1
(43) Pub. Date: Nov. 20, 2008

(54) Dual-Gate Transistors

(76) Inventors: Lay-Lay Chua, Singapore (SG); Peter Kian-Hoon Ho, Singapore (SG); Richard Henry Friend, Cambridge shire (GB)

Correspondence Address: SUGHRUE MION, PLLC, 2100 PENNSYLVANIA AVENUE, N.W., SUITE 800, WASHINGTON, DC, 20037, US

(21) Appl. No.: 11/547,269

(22) PCT Filed: Apr. 5, 2005
(86) PCT No.: PCT/GB2005/001309

§ 371 Date: Dec. 19, 2007

(30) Foreign Application Priority Data
Apr. 5, 2004 (GB) 0407739.2

(51) Int. Cl. H01L 51/05

(52) U.S. Cl. 257/40; 257/E51.005

(57) ABSTRACT

A field effect transistor device comprising: a source electrode; a drain electrode; a semiconductive region comprising an organic semiconductor material and defining a channel of the device between the source electrode and the drain electrode; a first gate structure comprising a first gate electrode and a first dielectric region located between the first gate electrode and the semiconductive region; and a second gate structure comprising a second gate electrode and a second dielectric region located between the second gate electrode and the semiconductive region; whereby the conductance of the semiconductor region in the channel can be influenced by potentials applied separately or to both the first gate electrode and the second gate electrode.

This invention relates to dual-gate transistors, especially organic dual-gate field effect transistors.

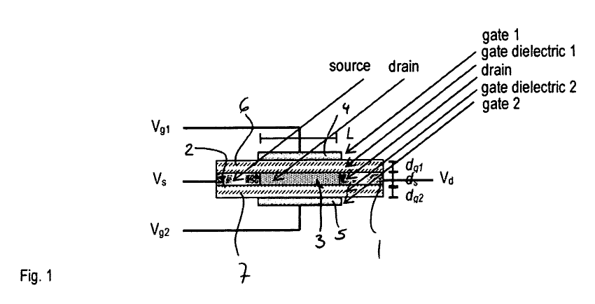

The physical layout of a dual-gate field-effect transistor (“DG-FET”) is described in relation to silicon-on-insulator technologies in the paper “Double-Gate Silicon-on-Insulator Transistor with Volume Inversion: A New Device with Greatly Enhanced Performance” (F. Balestra, S. Cristoloveanu, M. Benachir, J. Brini and T. Elewa, IEEE Electron Device Letters EDL-8 (1987) pp. 410-412). The schematic layout of the device is shown in FIG. 1. It is a four-terminal device which comprises a pair of a source electrode 1 and a drain electrode 2. The source and drain electrodes are separated from each other by a semiconducting channel 3 which is flanked by a pair of gate electrodes 4, 5. Each gate electrode is spaced from the source and drain electrodes and the channel by respective gate dielectrics 6, 7. The voltages on the source and drain electrodes are denoted Vₛ and V_{d} respectively. The gate voltages are denoted V_{g1} and V_{g2}, where V_{g1} is the voltage on gate electrode 4 and V_{g2} is the voltage on gate electrode 5. The thickness of gate dielectrics 6 and 7 are denoted d_{g1} and d_{g2} respectively, and the distance between the two semiconductor/dielectric interfaces is denoted dₛ. The channel length is denoted L.

As is described in the document, conducting channels can be activated in the device by biasing the gate electrodes 4, 5. The amount of coupling between the channels depends on details of construction of the device.

In the devices described in the above document, the semiconductor is a doped Si film (e.g. doped to a few 10¹⁵ cm⁻³ or more) that is operated in the traditional strong inversion regime by applying the appropriate bias to the two gate electrodes. When the applied gate bias is small dₛ is large and/or the doping-level is high, the depletion region is largely confined in the vicinity of the gate dielectric-semiconductor interfaces so that the coupling between the two conducting channels formed is insignificant. The device functions then essentially as two FETs connected in parallel. When the applied gate bias is large, dₛ is small and/or the doping-level is moderately low, strong coupling occurs between both the conducting channels as the depletion region overlaps in the centre of the bulk of the semiconductor. In this case, coupling of the two gates leads crucially to “volume inversion” of the bulk of the semiconductor (i.e. band bending everywhere exceeds 2_{φf} between the two gates, where φ_{f} is the energy difference between the Fermi level and the appropriate valence or conduction band edge and represents the severity of band-bending). As a result, advantages are claimed for silicon DG-FETs, including greatly increased minority carrier concentration leading to larger currents, reduced interface scattering and higher carrier mobility since the carriers are no longer confined to the interface, and enhanced operational speed and transconductance.

Although the structure of organic FETs superficially resembles that of Si MOSFETs in that both have source, drain and gate electrodes, their operation is fundamentally different. Organic FETs are operated with the semiconductor essentially undoped (typically with a doping level less than 10¹⁵ cm⁻³), whereas silicon devices are deliberately either n- or p-doped (typically with a doping level greater than 10¹⁵ cm⁻³). Also, organic FETs are typically turned on when the applied gate bias causes accumulation of charge carriers injected from the contacts, whereas silicon FETs are typically turned on when the applied gate bias causes an inversion of the sign of the charge-carriers at the interface backed by the formation of an depletion region comprising a space-charge of the ionized dopants.

As a result, while some of the known properties of silicon DG-FETs may also be relevant in organic DG-FET devices, the crucial feature of “volume inversion” is not pertinent in organic FETs.

According to one aspect of the present invention there is provided a field effect transistor device comprising: a source electrode; a drain electrode; a semiconductive region comprising an organic semiconductor material and defining two channels of the device between the source electrode and the drain electrode; a first gate structure comprising a first gate electrode and a first dielectric region located between the first gate electrode and the semiconductive region; and a second gate structure comprising a second gate electrode and a second dielectric region located between the second gate electrode and the semiconductive region; whereby the conductance of each of the two channels in the semiconductor region can be influenced by potentials applied to both the first gate electrode and the second gate electrode.

The organic semiconductor material is preferably a conjugated polymer, oligomer or small molecule material, or a mixture of any two or more of those.

The doping level of the semiconductive region is preferably less than 10¹⁵ cm⁻³.

The first gate structure is preferably located on the opposite side of the semiconductive region from the second gate structure.

The length of the channel in the direction between the source electrode and the drain electrode may be greater than the distance between the first gate electrode and the second gate electrode.

The conductance of the semiconductor region in the channel can preferably be influenced to permit current flow between the source electrode and the drain electrode only by means of a potential being applied to both the first gate electrode and the second gate electrode.

The first gate electrode may be electrically connected to the second gate electrode.

The length of the channel in the direction between the source electrode and the drain electrode may be less than the distance between the first gate electrode and the second gate electrode.

The length of the channel in the direction between the source electrode and the drain electrode may be equal to the distance between the first gate electrode and the second gate electrode.

The conductance of the semiconductor region in the channel can preferably be influenced to permit current flow between the source electrode and the drain electrode by means of a potential being applied to either the first gate electrode or the second gate electrode.

Preferably at least one of the first dielectric region and the second dielectric region comprises an organic dielectric material.

Preferably at least one of the first gate electrode and the second gate electrode comprises an organic electrically conductive material.

The invention also provides a logic element comprising such a field effect transistor.

The first and second gate electrodes may constitute inputs of the device. The source electrode may be connected to a predetermined voltage level. The drain electrode may constitute an output of the device. Alternatively the inputs and outputs may be arranged the opposite way around.

The semiconductive region is suitably a p-type semiconductive region. In that case the device may behave as a NOR gate. Alternatively the semiconductive region may be a n-type semiconductive region, and the device may behave as a NAND gate.

The invention also provides a logic circuit comprising such a logic element or a plurality thereof. The plurality of logic elements may be interconnected, optionally with other elements to form a logic circuit. The plurality of logic elements are preferably formed on a common substrate, most preferably as an integrated circuit.

The invention also provides a storage element comprising a field effect transistor device as set out above, the storage element having: a data write input whereby data can be written to the storage element, the data write input being connected to the first gate electrode; and a data read input whereby reading of data from the storage element can be initiated, the data read input being connected to the second gate electrode; whereby on application to the data read input of a signal sufficient to permit conductance in the channel associated with the second gate electrode the presence or absence at the data write input of a signal sufficient to permit conductance in the channel associated with the first gate electrode can be detected by sensing the conductance between the source electrode and the drain electrode.

The present invention will now be described by way of example with reference to the accompanying drawings, in which:

FIG. 1 shows a schematic diagram of a prior art silicon dual-gate FET in vertical cross-section.

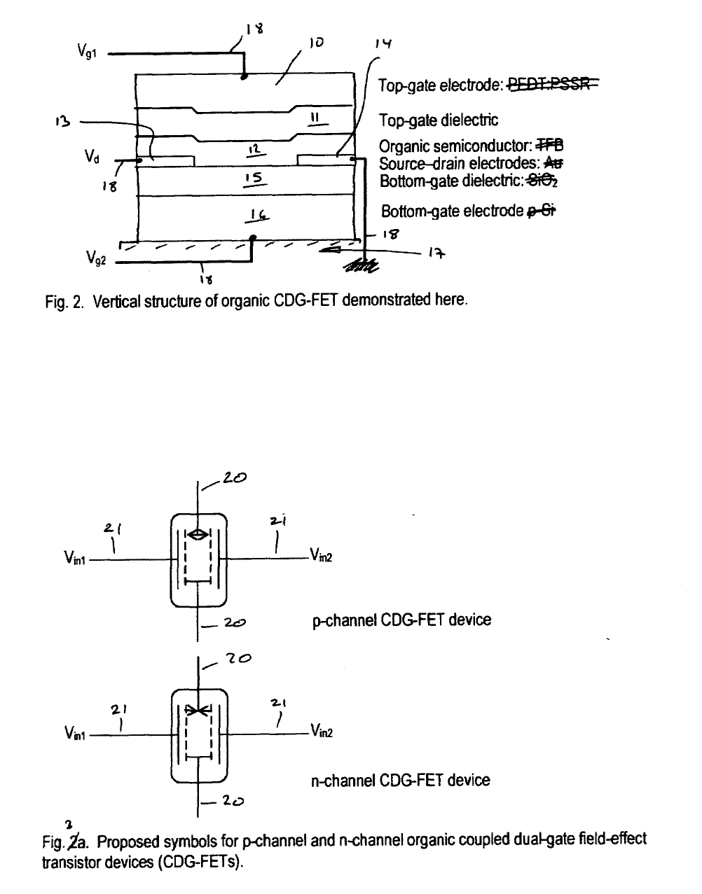

FIG. 2 shows a schematic diagram of an organic dual-gate FET in vertical cross-section.

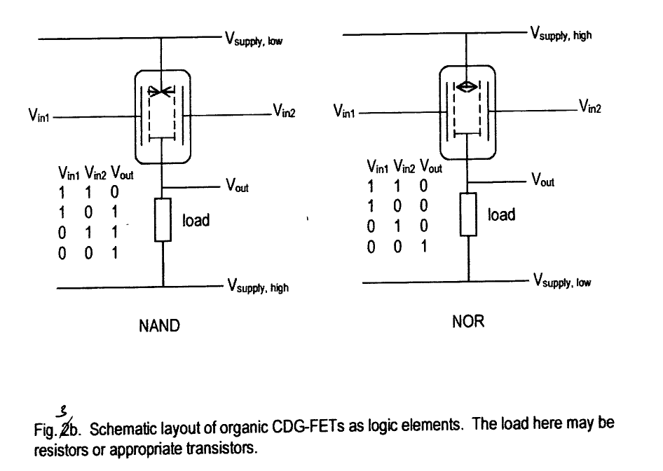

FIG. 3a shows symbols indicating p-channel and n-channel organic coupled dual-gate field-effect transistor devices (CDG-FETs).

FIG. 3b shows a schematic layout of organic CDG-FETs as logic elements. The load may, for example, be resistors or appropriate transistors.

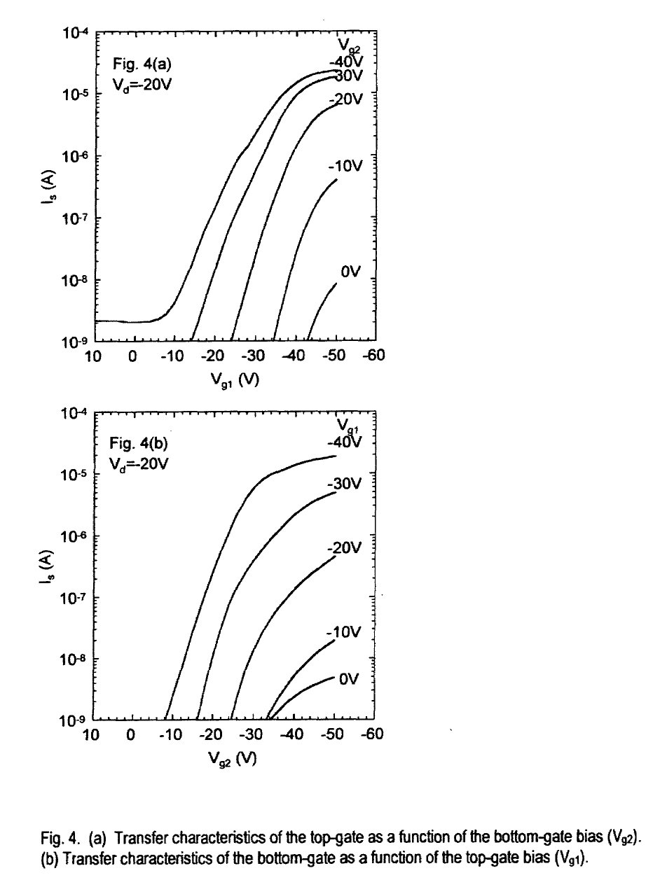

FIG. 4 shows the behaviour of example devices.

FIG. 2 shows schematically an organic dual-gate field effect transistor according to one example of the present invention. The device of FIG. 2 comprises a series of regions 10 to 16 which have been deposited as a series of layers or part-layers on a substrate 17. The regions comprise:
a conductive region 16 serving as a bottom gate electrode;
a dielectric region 15 serving as a bottom gate dielectric;
a pair of conductive regions 13, 14 which serve as drain and source electrodes respectively;
a semiconductive region 12 serving as the active semiconductive region of the device;
a dielectric region 11 serving as a top gate dielectric; and
a conductive region 10 serving as a top gate electrode.

The source and drain electrodes 14, 13 do not contact each other but are spaced apart by the semiconductive region 12, with which they are in contact. The semiconductive region 12 is generally planar. One major face of the semiconductive region 12 contacts the dielectric region 15. Opposing the semiconductive region 12 across that dielectric region is gate electrode 16, which is spaced from the semiconductive region 12 by that dielectric region 15. The other major face of the semiconductive region 12 contacts the dielectric region 11. Opposing the semiconductive region 12 across that dielectric region is gate electrode 10, which is spaced from the semiconductive region 12 by that dielectric region 11. Thus, the device has a single semiconductor region 12 which contacts both dielectric regions 11, 15 and can be influenced through both of those dielectric regions by the potential of both gate electrodes 10, 16. The dielectric regions 11, 15 are opposed across the semiconductor region 12.

In accordance with the invention, the semiconductor region is a region of an organic semiconductor. The device may therefore be termed an organic DG-FET. Preferably the semiconductor region consists, at least essentially, of one or more organic semiconductive materials. The or each such material could, for example, be a polymer (e.g. a conjugated polymer), oligomer or small-molecule material. The semiconductor region is preferably essentially undoped, for example having a doping level less than 10¹⁵ cm⁻³.

It is preferred that one or both of the dielectric regions are regions of organic dielectric. Preferably one or both of them consist (at least essentially) independently of one or more organic dielectric materials.

It is preferred that any one or more of the gate regions are regions of organic conductor. Preferably each of them consists (at least essentially) independently of one or more organic conductive materials or metal/conductive inks.

The semiconductor layer preferably comprises one or more organic semiconductive polymers. Examples of such polymers include poly(fluorene) homopolymers and copolymers, poly(p-phenylenevinylene) homopolymers and copolymers, poly(oxadiazole) homopolymers and copolymers, poly(thiophene) homopolymers and copolymers, poly(quinoxaline) homopolymers and copolymers, and homopolymers and copolymers that include one or more groups selected from benzothiadiazole, thiophene, benzene, naphthalene, acene, perylenetetracarboxylic diimide, naphthalenetetracarboxlic dianhydride, quinoline, benzimidiazole, oxadiazole, quinoxalines, pyridines, benzothiadiazole, acridine, phenazine, and tetraazaanthracene. The repeat units in the or each semiconductive polymer may be substituted or unsubstituted. Suitable substituents include functional substituents to enhance particular properties of the polymer such as solubility. The or each semiconductive polymer may be in the form of a cross-linked derivative, for example it may be a cross-linked derivative of any of the above polymers.

The semiconductor layer may comprise one or more oligomers, optionally together with one or more semiconductive polymers of the types identified above. The or each oligomer may be an oligomer of the polymers identified above.

In some embodiments, the semiconductive polymer may be made from a precursor polymer. Such a precursor may be converted to the final semiconductive polymer by appropriate reaction. For example, where the final semiconductive polymer is crosslinked, a precursor semiconductive polymer may contain crosslinkable groups and the crosslinked semiconductive polymer may be formed from the precursor by heating, for example.

The semiconductor layer may comprise one or more semiconductive small molecule species, optionally together with one or more semiconductive polymers or oligomers of the types identified above. Some examples of suitable semiconductive small molecules are: pentacene, phthalocyanines, bistriarylamines, perylenetetracarboxylic dianhydride and diimide, naphthalenetetracarboxlic dianhydride and diimide.

The gate dielectric layers preferably comprise an organic insulating polymer. Examples of insulating polymers which can be used after appropriate purification, are given below:

(i) Poly(siloxanes) and copolymers thereof; such as poly(dimethylsiloxane), poly(diphenylsiloxane-co-dimethyl-siloxane), and copolymers thereof.
(ii) Poly(alkenes) and copolymers thereof; such as atactic polypropylene, poly(ethylene-co-propylene), polyisobutylene, poly(hexene) and copolymers thereof;
(iii) Poly(oxyalkylenes) and copolymers thereof, such as poly(oxymethylene), poly(oxyethylene), and copolymers thereof;
(iv) Poly(styrene) and copolymers thereof.

The repeat units in the above polymers may be substituted or unsubstituted. Substituents include functional substituents to enhance particular properties of the polymer such as solubility. Crosslinked derivatives of the above polymers may also be used.

The gate dielectric layers are preferably, but not necessarily, of the same material.

The or each material used for a gate dielectric should be compatible with the overall processing scheme chosen for the device as a whole, and most preferably that of typical organic (particularly polymer) FETs. For example, its formation should preferably not destroy or functionally impair earlier formed layer integrities, while it itself should be capable of surviving subsequent solvent and thermal processing (if any) without impairment.

The conductor layer preferably is a metal layer, preferably deposited by physical vapour deposition, or sputtering, or as a colloid (for example, gold or silver or platinum or graphite), or by electroless deposition methods (e.g. gold or silver or other metals); or an electrically-conductive polymer, such as (poly(3,4-ethylenedioxythiophene) doped with polystyrenesulfonate (PEDT:PSSH), or a composite of the above.

In one example, the substrate could be a silicon substrate; the bottom gate electrode 16 could be of highly doped p-type silicon; the bottom gate dielectric could be of SiO₂; the source and drain electrodes could be of Au; the semiconductor could be a conjugated polymer such as TFB (poly(9,9-dioctylfluorene-co-(phenylene-(N-4-sec-butylphenyl)-iminophenylene)); the top gate dielectric could be of cross-linked BCB (benzocyclobutene); and the top gate electrode could be of hexadecyltrimethyl ammonium surfactant ion-exchanged PEDT:PSS (poly(3,4-ethylenedioxythiophene) doped with polystyrenesulfonate to render it conductive).

As indicated in FIG. 2, external connections 18 can be made to the electrodes 10, 12, 14 and 16 in order that the device can be used. The device may then be encapsulated for protection. For convenience the source electrode will be considered herein to be connected to ground, and the voltages on the top gate 10, drain 13 and bottom gate 16 will be denoted V_{g1}, V_{d} and V_{g2} and measured relative to the potential of the source electrode.

The device may be viewed as comprising two back-to-back FETs sharing the same source, drain and semiconductor regions. The first FET comprises gate 10, dielectric 11 and source, drain and semiconductor 14, 13, 12. The second FET comprises gate 16, dielectric 15 and source, drain and semiconductor 14, 13, 12.

The thicknesses of the top gate dielectric 11, semiconductor 12 and bottom gate dielectric 15 are denoted d_{g1}, dₛ and d_{g2} respectively. The channel length is denoted L. d_{g1} and d_{g2} should preferably be selected on the basis of a scaling relationship with respect to L. Typically, d_{g1} and d_{g2} may be independently selected to be between 1/10 and 1/20 of L.

Although the structure of this organic DG-FET thus superficially resembles that of the above silicon DG-FETs in that both have source, drain and dual-gate electrodes, the operation of the organic DG-FET is fundamentally different from that of silicon DG-FETs. The crucial difference is that the semiconductor does not rely on dopant for its electrical properties and so volume inversion does not take place. As a result, gate coupling in an organic DG-FET such as that of FIG. 2 is controlled primarily by electrostatics via the d/L ratio, where d=d_{g1}+dₛ+d_{g2} (with d_{g1}, d_{g2}<<L) is the semiconductor thickness and L is the channel length; whereas in silicon DG-FETs by the dₛ/2d_{depl} ratio, where d_{depl} is the depletion width created during normal inversion operation of the device.

The inventors of the present invention have further identified that organic DG-FETs exhibit a remarkable and unexpected property. The two gate electrodes of a DG-FET can be coupled together, by having the d/L ratio suitably smaller than 1 (preferably smaller than 0.5) so that the two gates are held in close proximity to form what may termed a coupled DG-FET (CDG-FET). It is preferred that no active device is connected between the gates of the coupled-DG-FET; preferably the gates are connected together by an ohmic connection, most preferably a conductor extending from one to the other. The coupling here refers to the electrostatic influence of the voltage applied to one gate on the channel further away as a result of the physical proximity of the two channels. Therefore the operation of one gate and specifically the nature (voltage and/or current) of the signal applied to it influences or affects the channel next to the other gate. In the case of an organic CDG-FET, the transistor switches on (permitting current flow between source and drain) only when both gates are appropriately biased to the “on” state. When only one gate is biased to the “on” state, while the other gate is kept in the “off” state, the device remains in the “off” (non-conducting) state. This behaviour has been found to be qualitatively independent of the voltage used to bias the gates. The same behaviour is observed as long as one of the gates is biased in the voltage range that normally places the channel in the “on” state, while the other gate is biased in the voltage range that normally places the channel in the “off” state. This behaviour is fundamentally different from silicon CDG-FETs which turn on (become conducting) whenever one of the gates is biased “on”.

In addition to the qualitative difference in function, the design principle of organic CDG-FETs is also different from silicon CDG-FETs. In organic CDG-FETs, the d/L radio should suitably be less than 1 (for example, from 0.01 to 0.5). In some applications (for example in logic gates as described below), it is advantageous that the d_{g1}:d_{g2} ratio should preferably be chosen such that their capacitances are matched or nearly matched—preferably to within 10%—in order that the operation of the device is balanced. In contrast, in silicon CDG-FETs the requirement is for dₛ/2d_{depl}<1, where d_{depl} is the depletion width created during normal inversion operation of the device.

One application of an organic CDG-FET is as a logic element. As a result of the behaviour described above, organic CDG-FETs can be used as logic elements in MOS-type logic families. This logic element functionally resembles two transistors connected in series. Used in this way the device presents several advantages over single-gate FETs (SG-FETs) in logic circuits:
1. The number of transistor components is reduced by half, since one DG-FET replaces two single gate FETs.
2. The two back-to-back transistors in the DG-FET can share the same real-state area on a substrate, and hence the total footprint is reduced by half.
3. The two channels in the DG-FET share the same semiconductor, and hence their properties can be more nearly matched than two SG-FETs fabricated separately, and they suffer less from differential effects such as those due to thermal or process variations.

When the device of FIG. 2 is used in this way in a logic circuit such a p-channel CDG-FET would provide a NOR logical operation in the configuration shown, while an n-channel CDG-FET would provide a NAND operation. In each case the inputs would be connected to electrodes 10 and 16 and the input and output to electrodes 13 and 14. An inverter can be obtained by tying both inputs together. Symbols depicting p- and n-channel forms of operation are shown in FIG. 3a. In FIG. 3a lines 20 denote the two source/drain connections to each device and lines 21 denote the two gate connections to each device. The load can be a resistor or more preferably a transistor operated in the opposite carrier type to the first transistor. Circuits and truth-tables depicting NAND and NOR operation of p- and n-channel devices are shown in FIG. 3b. Together all the other logical operations, OR, AND, XOR, can be constructed from such a building block.

Another application of an organic DG-FET is as transmission gate. In this configuration one gate (the write gate) of the organic DG-FET is used to write the state of the transistor, while the second gate (the control gate) is used for a control input to read the state of the transistor. The organic DG-FET provides a compact means of achieving such functionality. When the control input puts the control gate in the “off”-state, the transistor is non-conducting whatever the state of the write gate. When the control input puts the control gate in the “on”-state, the transistor becomes conducting if the write gate is also in the “on”-state but remains non-conducting if the write gate is in the “off”-state. In this way, the state of the transistor can be written and/or read and passed on to other devices.

The dₛ/L ratio of the organic DG-FET can be made relatively large: for example greater than 1. With a sufficiently large dₛ/L ratio the two gates function as parallel-connected FETs. This can be achieved by fabricating a thick semiconductor layer between the two gate dielectrics, or if this is inconvenient, alternatively by fabricating a dielectric spacer layer—in the middle of the thickness of the device. This spacer layer would divide the semiconductor layer in two, so as to separate the semiconductor adjacent to one dielectric layer from that adjacent the other dielectric layer. Such decoupled organic DG-FETs can then be used as OR logic elements, while retaining similar space and fabrication advantages as organic CDG-FETs

An example of the fabrication of an organic coupled DG-FET as shown schematically in FIG. 2 will now be described. The structure is asymmetric and is presented purely to illustrate the principles involved because of the easy availability of prefabricated Si/SiO₂ structures. It is straightforward and in many cases more desirable to use other materials for the substrate (for instance high-performance engineering plastics such as polyimides, poly(ethyleneterephthalates), poly(vinylidenechloride) and their laminates), gate (for example, conducting polymers, metal nanoparticles and electroless metallisation) and gate dielectric (high-dielectric strength insulating polymers such as benzocyclobutene-siloxane-based materials). In this example a p-doped Si wafer was used as the substrate and bottom-gate (g2) 16 of the coupled dual-gate FET and served as a substrate for supporting subsequently deposited layers. The wafer had an upper layer of 200-nm thermal SiO₂ to act as the gate dielectric 15. 15-nm-thick Au layer was then fabricated in an interdigitated array pattern by standard photolithography lift-off processes to form the source and drain electrodes 14, 13. The dimensions of the pattern were selected to give 3-μm channel length and 10-mm channel width of the transistor. The substrate was then cleaned with a final step of oxygen plasma, water-rinse followed by N₂ blow dry, and then methylated with hexamethyldisilazane. 70-nm-thick poly(9,9-dioctylfluorene-co-(phenylene-(N-4-sec-butylphenyl)-iminophenylene) (“TFB”) was then deposited from a mesitylene solution to give the organic semiconductor 50-nm-thick thin film 12. 150-nm BCB was then deposited from a decane solution and thermally crosslinked at 290° C. (9 s) in glovebox (O₂ level<5 ppm) to give the top gate dielectric 11. Hexadecyltrimethylammonium surfactant-ion-exchanged poly(3,4-ethylenedioxythiophene)-polystyrenesulfonate (“PEDT:PSSR”) was then printed over the interdigitated array to give the top-gate contact 10.

The transfer characteristics of the top-gate of this device are shown in FIG. 4(a). For a fixed V_{d}=−20V, the drain current (I_{d}) increases generally with increasing −V_{g1}, as is expected in standard single-gate p-channel organic FETs. However both the current and top-gate transconductance (∂I_{d}/∂V_{g1}) at any given V_{g1} value are strongly dependent on the bottom-gate bias (V_{g2}). In particular, when V_{g2} is less than the bias required to turn on conduction at the bottom-gate in a single-gate device, both the current and top-gate transconductance are strongly suppressed (e.g. by more than 3 orders of magnitude at V_{g2}=0V). Only when the bottom-gate is sufficiently biased into conduction (i.e. −V_{g2}>25 V for this example) does the top-gate transconductance develop fully and become normal in appearance. Further biasing the bottom-gate far above the “on”-state (e.g. −V_{g2}>35 V) leads to quasi-saturation in the sense that its effect on the top-gate transconductance characteristic becomes markedly weaker. It should be noted that the relatively large threshold voltage observed in this example is believed to be due to impurity ion concentration present in the polymer from which the example device was made, and the use of “cleaner” materials would readily provide a threshold nearer to zero.

Conversely, the same effect is observed in the bottom-gate transconductance characteristic as a function of top-gate bias (V_{g1}), as shown in FIG. 4(b).

A cross-transconductance of gate-2 can be defined to quantify the effect of the gate-2 on the transconductance of the gate-1 as the fractional change in the transconductance of the proximal gate (gate-1) with the bias applied to remote gate (gate-2), according to:

$${S}_{21} = \frac{1}{( \frac{\partial {l}_{d}}{\partial {V}_{g 1}} )} \frac{\partial ( \frac{\partial {l}_{d}}{\partial {V}_{g 1}} )}{\partial {V}_{g 2}} = \frac{\partial ( ln ( \frac{\partial {l}_{d}}{\partial {V}_{g 1}} ) )}{\partial {V}_{g 2}}$$

and vice versa (with interchange of the remote and proximal gates):

$${S}_{12} = \frac{1}{( \frac{\partial {l}_{d}}{\partial {V}_{g 2}} )} \frac{\partial ( \frac{\partial {l}_{d}}{\partial {V}_{g 2}} )}{\partial {V}_{g 1}} = \frac{\partial ( ln ( \frac{\partial {l}_{d}}{\partial {V}_{g2}} ) )}{\partial {V}_{g 1}}$$

Both cross-transconductances are large and relatively constant over a wide range of the proximal gate voltages (here S≈0.1 decade/V) for remote gate bias below its turn-on value. Very quickly after the remote gate is turned on, the device source-drain current characteristic reaches “saturation” in the sense that the source-drain current and device conductivity reaches a maximum value set by the proximal gate bias with less dependence on the value of the remote gate bias (i.e., S≈0). Thus by switching the remote gate bias between the “on” and “off” states, one can usefully allow a second signal to control the source-drain current and device conductivity.

The slight difference in the value of the cross-transconductances in the experimental observations (in which cross-transconductance of top-gate is persistently larger than that of the bottom-gate at high bias) can be explained by the slight asymmetry of the gate capacitances (here, C_{g1}≈0.85 C_{g2}) such that a larger bias threshold for conduction is required for the top-gate than the bottom-gate.

As described above, the organic CDG-FET is brought into conduction only by simultaneously applying “on” gate biases to both gates. This fundamental effect distinguishes such organic CDG-FETs from silicon CDG-FETs and enables the interesting new applications discussed above.

Devices could be made in which all the layers were formed of organic materials, for example by ink-jet deposition of each layer from solution, the solvents for each layer having been selected so as not to dissolve at least the immediately underlying layer(s).

Devices could be made in which more than two gate structures can influence the semiconductor region.

As illustrated in FIG. 2, the semiconductor region 12 preferably overlaps the source and drain electrodes 13 and 14 in the plane of the layers of the device. The source and drain electrodes are preferably in the same plane.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

1. A field effect transistor device comprising:
a source electrode;
a drain electrode;
a semiconductive region comprising an organic semiconductor material and defining two channels of the device between the source electrode and the drain electrode;
a first gate structure comprising a first gate electrode and a first dielectric region located between the first gate electrode and the semiconductive region; and
a second gate structure comprising a second gate electrode and a second dielectric region located between the second gate electrode and the semiconductive region;
whereby the conductance of each of the two channels in the semiconductor region can be influenced by potentials applied to both the first gate electrode and the second gate electrode.

2. A field effect transistor device as claimed in claim 1, wherein the organic semiconductor material is a conjugated polymer, oligomer or small molecule material.

3. A field effect transistor device as claimed in claim 1, wherein the doping level of the semiconductive region is less than 10¹⁵ cm⁻³.

4. A field effect transistor device as claimed in claim 2, wherein the first gate structure is located on the opposite side of the semiconductive region from the second gate structure.

5. A field effect transistor device as claimed in claim 4, wherein the length of the channel in the direction between the source electrode and the drain electrode is greater than the distance between the first gate electrode and the second gate electrode.

6. A field effect transistor as claimed in claim 5, wherein the conductance of the semiconductor region in the channel can be influenced to permit current flow between the source electrode and the drain electrode only by means of a potential being applied to both the first gate electrode and the second gate electrode.

7. A field effect transistor device as claimed in claim 1, wherein the first gate electrode is electrically connected to the second gate electrode.

8. A field effect transistor device as claimed in claim 4, wherein the length of the channel in the direction between the source electrode and the drain electrode is less than the distance between the first gate electrode and the second gate electrode.

9. A field effect transistor device as claimed in claim 8, wherein the conductance of the semiconductor region in the channel can be influenced to permit current flow between the source electrode and the drain electrode by means of a potential being applied to either the first gate electrode or the second gate electrode.

10. A field effect transistor device as claimed in claim 1, wherein at least one of the first dielectric region and the second dielectric region comprises an organic dielectric material.

11. A field effect transistor device as claimed in claim 1, wherein at least one of the first gate electrode and the second gate electrode comprises an organic electrically conductive material.

12. A logic element comprising a field effect transistor device as claimed in claim 1.

13. A logic element as claimed in claim 12, wherein the first and second gate electrodes constitute inputs of the device, the source electrode is connected to a predetermined voltage level and the drain electrode constitutes an output of the device or vice versa.

14. A logic element as claimed in claim 13, wherein the semiconductive region is a p-type semiconductive region, and the device behaves as a NOR gate.

15. A logic element as claimed in claim 13, wherein the semiconductive region is a n-type semiconductive region, and the device behaves as a NAND gate.

16. A logic circuit comprising a logic element as claimed in claim 12.

17. A logic circuit as claimed in claim 16, comprising a plurality of logic elements as claimed in claim 12 integrated on a single substrate.

18. A storage element comprising a field effect transistor device as claimed in claim 6, the storage element having:
a data write input whereby data can be written to the storage element, the data write input being connected to the first gate electrode; and
a data read input whereby reading of data from the storage element can be initiated, the data read input being connected to the second gate electrode;
whereby on application to the data read input of a signal sufficient to permit conductance in the channel associated with the second gate electrode the presence or absence at the data write input of a signal sufficient to permit conductance in the channel associated with the first gate electrode can be detected by sensing the conductance between the source electrode and the drain electrode.

19. (canceled)
